(19) United States
(12) Patent Application Publication
(10) Pub. No.: US 2026/0371812 A1
(43) Pub. Date: Nov. 19, 2026

(54) DRIVING BACKPLANE, DISPLAY PANEL AND DISPLAY DEVICE

(71) Applicants: Beijing BOE Technology Development Co., Ltd., Beijing (CN); BOE TECHNOLOGY GROUP CO., LTD., Beijing (CN)

(72) Inventors: Jing NIU, Beijing (CN); Fangzhen ZHANG, Beijing (CN); Yanan NIU, Beijing (CN); Shuang SUN, Beijing (CN); Wei WANG, Beijing (CN)

(21) Appl. No.: 19/124,302

(22) PCT Filed: Nov. 30, 2023
(86) PCT No.: PCT/CN2023/135615

§ 371 Date: Apr. 25, 2025

(51) Int. Cl. H10H 29/49

(52) U.S. Cl. CPC H10H 29/49

(57) ABSTRACT

The present disclosure relates to a driving backplane and a display panel, and relates to the field of display technology. The driving backplane includes a substrate, a circuit layer and a binding layer, where the circuit layer is provided on a side of the substrate; the binding layer is provided on a side of the circuit layer away from the substrate; the binding layer includes a plurality of pads distributed in an array. The pad includes a welding part and a flow limiting groove located outside the welding part, and the boundary of the pad is located outside the flow limiting groove; and/or, blocking structures are provided between the pads and are spaced apart from the pads, and the blocking structures are insulated from the pads.

### CROSS-REFERENCE TO RELATED APPLICATIONS

The present application is a U.S. National Stage of International Application No. PCT/CN2023/135615, filed on Nov. 30, 2023, the content of which is incorporated by reference herein in its entirety for all purposes.

### TECHNICAL FIELD

The present disclosure relates to the field of display technology, and in particular to a driving backplane, a display panel and a display device.

### BACKGROUND

Display panels that use LEDs such as Micro LED (micro light-emitting diode) and Mini LED (mini light-emitting diode) directly as pixelated light-emitting devices have the advantages of low power consumption, high brightness, high resolution, high color saturation, fast response speed, long life, and high efficiency. However, the light-emitting devices in existing display panels of this type may short-circuit, causing display abnormalities or even failure to display.

It should be noted that the information disclosed in the above background technology section is only used to enhance the understanding of the background of the present disclosure, and therefore may include information that does not constitute prior art known to those skilled in the art.

### SUMMARY

The present disclosure provides a driving backplane, a display panel and a display device.

According to an aspect of the present disclosure, there is provided a driving backplane, including:
a substrate;
a circuit layer, provided on a side of the substrate;
a binding layer, provided on a side of the circuit layer away from the substrate, where the binding layer includes a plurality of pads distributed in an array;
where each of the pads includes a welding part and a flow limiting groove located outside the welding part, and a boundary of the pad is located outside the flow limiting groove; and/or, blocking structures spaced apart from the pads are provided between the pads, and the blocking structures are insulated from the pads.

According to an aspect of the present disclosure, there is provided a display panel, including:
the driving backplane according to any one of the above items; and
a plurality of light-emitting devices, any one of the light-emitting devices is welded with the welding part of at least one pad through a conductive solder.

According to an aspect of the present disclosure, there is provided a display device, including the display panel according to any one of the above items.

It is to be understood that the foregoing general description and the following detailed description are exemplary and explanatory only and are not restrictive of the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. Obviously, the drawings described below are only some embodiments of the present disclosure. For those skilled in the art, other drawings can also be obtained based on these drawings without inventive work.

FIG. 1 is a top view schematic diagram of an embodiment of a display panel of the present disclosure.

FIG. 2 is a partial cross-sectional view of a display panel of a first type of embodiment according to a first conception.

FIG. 3 is a partial cross-sectional view of a display panel of a first type of embodiment according to a first conception.

FIG. 4 is a partial cross-sectional view of a driving backplane of a first type of embodiment according to a first conception.

FIG. 5 is a partial cross-sectional view of a driving backplane of another first type of embodiment according to a first conception.

FIG. 6 is a top view of a part of pads of a first one of a first type of embodiment according to a first conception.

FIG. 7 is a top view of a part of pads of a second one of a first second of embodiment according to a first conception.

FIG. 8 is a top view of a part of pads of a third one of a first type of embodiment according to a first conception.

FIG. 9 is a top view of a part of pads of a first one of a second type of embodiment according to a first conception.

FIG. 10 is a top view of a part of pads of a second one of a second type of embodiment according to a first conception.

FIG. 11 is a top view of a part of pads of a third one of a second type of embodiment according to a first conception.

FIG. 12 is a top view of a part of pads of a fourth one of a second type of embodiment according to a first conception.

FIG. 13 is a top view of a part of pads of a fifth one of a second type of embodiment according to a first conception.

FIG. 14 is a top view of a part of pads of an embodiment according to a second conception.

FIG. 15 is a top view of a part of pads of a second type of embodiment according to a second conception.

FIG. 16 is a top view of a part of pads of a third type of embodiment according to a second conception.

FIG. 17 is a partial cross-sectional view of a part of a display panel of an embodiment according to a third conception.

FIG. 18 is a partial top view of a driving backplane of an embodiment according to a third conception.

FIG. 19 is a partial cross-sectional view of a display panel of an embodiment combining the first and third concepts.

### DETAILED DESCRIPTION

The example embodiments will now be described more fully with reference to the accompanying drawings. However, the example embodiments can be implemented in a variety of forms and should not be construed as being limited to the embodiments set forth herein; rather, these embodiments are provided so that the present disclosure will be comprehensive and complete and the concept of the example embodiments will be fully conveyed to those skilled in the art. The same reference numerals in the figures represent the same or similar structures, and their detailed descriptions will be omitted. In addition, the drawings are only schematic illustrations of the present disclosure and are not necessarily drawn to scale.

The terms “a”, “an”, “the”, “said”, and “at least one” are used to indicate the presence of one or more elements/components/etc.; the terms “including” and “having” are used to indicate an open-ended inclusion and mean that there may be additional elements/components/etc. in addition to the listed elements/components/etc.; the terms “first” and “second” are used only as markers and are not intended to limit the number of their objects.

The row direction X and the column direction Y herein are two intersecting directions, which may be mutually perpendicular directions. For example, in the drawings of the present disclosure, the row direction X may be horizontal and the column direction Y may be vertical; but it is not limited to this, and the row direction X and the column direction Y may also be non-perpendicular directions. In addition, those skilled in the art may know that as the display panel rotates, the actual orientations of the row direction X and the column direction Y may change, but the relative positions of the two remain unchanged.

A and B “provided on a same-layer” herein means that A and B belong to different regions of the same film layer, and the film layer may be a single-layer structure; or, the film layer may also be a multi-layer structure, in which case A and B may be provided at a same layer or different layers in the multiple layers.

The embodiment of the present disclosure provides a display panel, as shown in FIG. 1. The display panel may include a display area AA and a peripheral area WA located outside the display area AA. The peripheral area WA may be a continuous annular area surrounding the display area AA, or may be a discontinuous area surrounding the display area AA.

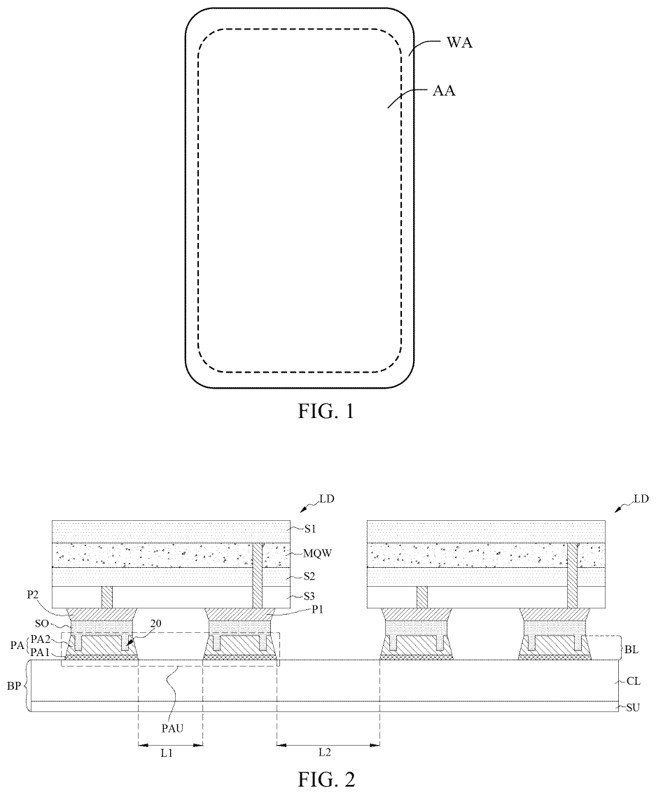

As shown in FIG. 2, the display panel may include a driving backplane BP and a plurality of light-emitting devices LD provided on one side of the driving backplane BP. Each light-emitting device LD is located in the display area AA, and is distributed along the row direction X and the column direction Y. The light-emitting devices LD may be driven to emit light by the driving circuit in the driving backplane BP to display an image.

As shown in FIG. 2, the light-emitting device LD may be a Micro-LED or a Mini LED, where the size of the Micro LED is below 100 μm, and the size of the Mini LED is between 100 and 300 μm. Of course, other light-emitting devices may also be used.

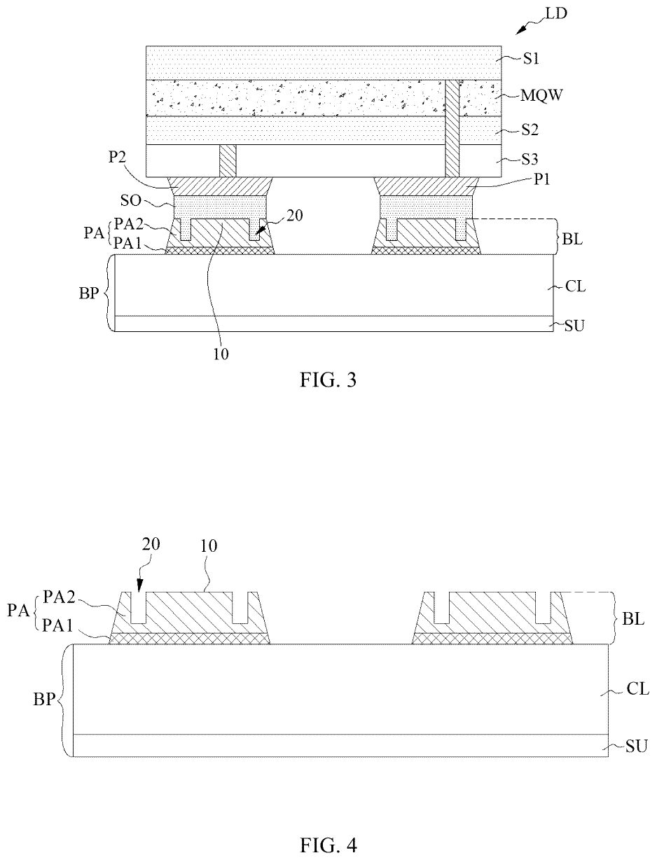

As shown in FIG. 2 and FIG. 3, in some embodiments of the present disclosure, the light-emitting device LD may include a first electrode P1, a second electrode P2, and a first semiconductor layer S1, a light-emitting functional layer MQW, and a second semiconductor layer S2 stacked in sequence. One of the first semiconductor layer S1 and the second semiconductor layer S2 may be an N-type semiconductor layer, and the other may be a P-type semiconductor layer. The first semiconductor layer S1 and the second semiconductor layer S2 may form a PN junction. The first electrode P1 is connected to the first semiconductor layer S1, and the second electrode P2 is connected to the second semiconductor layer S2. Both the first electrode P1 and the second electrode P2 are connected to the above-mentioned pixel circuit. By applying an electrical signal to the first electrode P1 and the second electrode P2, light may be emitted from the light-emitting functional layer MQW.

For Mini LED, the light-emitting device LD may also include a substrate, and the first semiconductor layer S1, the light-emitting functional layer MQW, and the second semiconductor layer S2 may be stacked in sequence on one side of the substrate. The substrate can be made of materials such as sapphire and silicon carbide, and the first semiconductor layer S1, the light-emitting functional layer MQW and the second semiconductor layer S2 are formed in sequence through an epitaxial process. The materials of the first semiconductor layer S1 and the second semiconductor layer S2 can be gallium nitride, gallium phosphide, etc., depending on the light-emitting color of the light-emitting device LD. The light-emitting functional layer MQW can be a quantum well layer. For Micro LED, the above-mentioned substrate only exists during the manufacturing process. After the manufacturing is completed, when the light-emitting devices LD are transferred to the driving backplane BP, the light-emitting devices LD do not have a substrate, that is, the substrate is peeled off from the first semiconductor layer S1, the light-emitting functional layer MQW and the second semiconductor layer S2.

The light-emitting device LD can adopt a face-up structure, a vertical structure and a flip-up structure. For example:

Taking the face-up structure as an example, the substrate of the light-emitting device LD is stacked on the driving backplane BP, and the first semiconductor layer S1, the light-emitting functional layer MQW and the second semiconductor layer S2 are distributed in sequence in a direction away from the driving backplane BP. The second semiconductor layer S2 and the light-emitting functional layer MQW expose part of the first semiconductor layer S1, that is, they do not completely cover the first semiconductor layer S1. The first electrode P1 may be provided on the surface where the first semiconductor layer S1 is exposed, and the second electrode P2 is provided on a surface of the second semiconductor layer S2 away from the driving backplane BP. That is, the first electrode P1 and the second electrode P2 are located on a side of the light-emitting device LD away from the driving backplane BP. The first electrode P1 and the second electrode P2 may be connected to the pixel circuit respectively through leads.

Taking the vertical structure as an example, the first electrode P1 of the light-emitting device LD is stacked on the driving backplane BP, and may be welded with the pad PA of the driving backplane BP through a conductive solder SO, and connected to the pixel circuit through the pad PA. The substrate, the first semiconductor layer S1, the light-emitting functional layer MQW, the second semiconductor layer S2 and the second electrode P2 are sequentially distributed in a direction away from the driving backplane BP. The second electrode P2 may be connected to the driving circuit through leads.

As shown in FIG. 2 and FIG. 3, taking the flip-chip structure as an example, the first electrode P1 and the second electrode P2 of the light-emitting device LD may be provided in the same layer, and both may be welded with the pad PA of the driving backplane BP through a conductive solder SO, thereby directly connecting the first electrode P1 and the second electrode P2 to the pixel circuit of the driving backplane BP. The second semiconductor layer S2, the light-emitting functional layer MQW and the first semiconductor layer S1 can be distributed in sequence in a direction away from the driving backplane BP. At the same time, an insulating layer S3 can be provided between the first electrode P1, the second electrode P2 and the second semiconductor layer S2. The first electrode P1 can be connected to the first semiconductor layer S1, and the second electrode P2 can be connected to the second semiconductor layer S2.

The above-mentioned first electrode P1 and second electrode P2 can be made of transparent conductive materials such as ITO (indium zinc oxide) and IZO (indium tin oxide), or metals such as titanium, aluminum, silver, and gold. The first electrode P1 and the second electrode P2 can be made of a single-layer or multi-layer structure, and the materials of different layers can be different.

The light-emitting device LD in the display panel can be divided into different pixels, and each pixel includes three or more light-emitting devices LD with different light-emitting colors. The light-emitting devices LD of the same pixel can be distributed linearly along the row direction X or the column direction Y; of course, the light-emitting devices LD of the same pixel are also distributed in a polygonal shape. For example, one pixel includes three light-emitting devices LD, and the three light-emitting devices LD can be distributed in a triangular shape. In addition, in the entire display panel, the light-emitting devices LD can be distributed in an array along the row direction X and the column direction Y, but the light-emitting devices LD of the same pixel are not necessarily located in the same row or the same column.

The structure of the driving backplane BP is described in detail below:

As shown in FIGS. 2-5, 17 and 19, the driving backplane BP may include a substrate SU, a circuit layer CL and a binding layer BL, where:

The substrate SU may be a single-layer structure or multi-layer structure, and its material may be a hard material such as glass, or a flexible material such as polyimide, and the material and structure of the substrate SU are not specifically limited here.

The circuit layer CL may be provided on one side of the substrate SU, and the circuit layer CL may include the above-mentioned driving circuit. The driving circuit may include a pixel circuit PC. The pixel circuit PC may be a pixel circuit such as 7T1C, as long as it can drive the light-emitting device LD to emit light, and its structure is not specifically limited here. Among them, nTmC means that a pixel circuit PC includes n transistors (represented by the letter “T”) and m capacitors (represented by the letter “C”). At least part of the pixel circuit may be located in the display area.

The number of pixel circuits PC may be the same as the number of light-emitting devices LD, and the pixel circuits PC are connected to the light-emitting devices LD in a one-to-one correspondence, so as to control each light-emitting device LD to emit light. Of course, the number of pixel circuits PC may be less than the number of light-emitting devices LD. For example, a same pixel circuit PC may also be connected to multiple light-emitting devices LD, and drive multiple light-emitting devices LD to emit light at the same time, which is not specifically limited here.

In addition, the driving circuit may also include a peripheral circuit located in the peripheral area WA, which may include a gate driving circuit, etc., for controlling the circuit of the pixel circuit, which may be configured to control the timing of the light-emitting device LD to emit light, and its specific structure is not specifically limited here.

The above-mentioned driving circuit may be formed by multiple film layers. For example, taking the thin film transistor with a top gate structure as an example, the driving backplane BP may include a semiconductor layer, a first gate insulating layer, a first gate layer, a second gate insulating layer, a second gate layer, a dielectric layer, at least one source and drain layer, and a planarization layer covering the source and drain layer which are stacked in a direction away from the substrate SU. If multiple source and drain layers are used, adjacent source and drain layers may be separated by a planarization layer. The active layer of each thin film transistor can be located in the semiconductor layer, and the gate electrode is located in the first gate layer. One plate of the capacitor can be located in the first gate layer, and the other plate can be located in the second gate layer. In addition, the first gate layer, the second gate layer and the source and drain layer can be provided with wiring or other connection structures for connecting the thin film transistor and the capacitor and transmitting signals, and the specific pattern of each film layer is not specifically limited here.

As shown in FIGS. 2-5, 17 and 19, the binding layer BL is provided on the side of the circuit layer CL away from the substrate SU. For example, the binding layer BL is provided on the surface of the planarization layer farthest from the substrate SU away from the substrate SU. The binding layer BL may include a plurality of pads PA distributed in an array. The pads PA may be connected to the pixel circuit, and the electrodes of the light-emitting devices LD may be electrically connected to the pads PA through the conductive solder SO, so that the light-emitting devices LD are bound to the driving backplane BP and connected to the pixel circuit.

For example, as shown in FIG. 2 and FIG. 3, for a light-emitting device LD of a vertical structure, the first electrode P1 can be welded to the pad PA of the driving backplane through the conductive solder SO. For a light-emitting device LD of a flip-chip structure, the first electrode P1 and the second electrode P2 provided in the same layer are both welded to the pads PA of the driving backplane BP through the conductive solder SO. That is, one light-emitting device LD of a vertical structure is welded to one pad PA, at which time, the number of pads PA is the same as the number of light-emitting devices LD; while one light-emitting device LD of a flip-chip structure needs to be welded to two pads PA, at which time, the number of pads PA is twice the number of light-emitting devices.

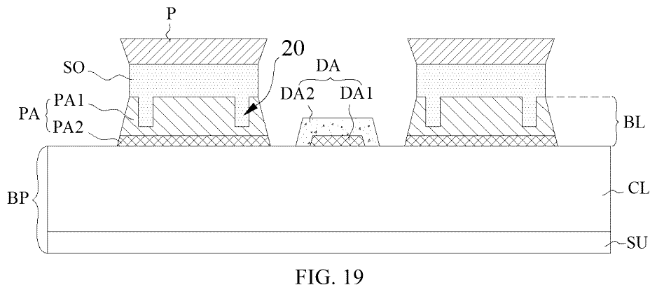

In addition, FIG. 17 and FIG. 19 show the welding of the electrode P of the light-emitting device LD to the pad PA, where the part of the light-emitting device LD other than the electrode P is omitted, and the two electrodes P can be two electrodes of the light-emitting device LD of the same flip-chip structure, or two electrodes of two light-emitting devices LD of vertical structure.

The melting point of the conductive solder SO is lower than the melting point of the pad PA. During the welding process, the conductive solder SO is melted by heat, and diffuses with the material of the pad PA to achieve eutectic bonding. For example, the conductive solder SO may be made of tin (Sn), and the pad PA may be a single-layer structure or a multi-layer structure, and its material may be copper (Cu) or gold (Au). Of course, the conductive solder SO and the pad PA may also be made of other conductive metals, alloys or non-metallic materials, as long as the melting point of the conductive solder SO is lower than that of the pad PA, and the two can form a eutectic bond.

As shown in FIG. 2 and FIG. 3, in some embodiments of the present disclosure, the pad PA may be formed by an electroplating process in conjunction with a photolithography process, which may include a seed layer PA1 and a conductive layer PA2. The seed layer PA1 may be provided on the surface of the planarization layer farthest from the substrate SU away from the substrate SU. The conductive layer PA2 is stacked on the surface of the seed layer PA1 away from the substrate SU, and the thickness of the conductive layer PA2 is greater than the thickness of the seed layer PA1. The seed layer PA1 may be made of copper, nickel, and copper-containing alloys or other materials, which may improve the adhesion of the conductive layer PA2. The conductive layer PA2 may be made of conductive metals such as copper and gold or other materials. The seed layer PA1 and the conductive layer PA2 can be formed by electroplating, sputtering and other processes, and patterning can be achieved by photolithography. Of course, in other embodiments of the present disclosure, the pad PA may not include the seed layer PA1, but only include the conductive layer PA2, and the conductive layer PA2 can be directly provided on the driving backplane. In addition, in some embodiments, the side wall of the seed layer PA1 and the side wall of the conductive layer PA2 can shrink in the direction away from the substrate SU. That is, the contour of the cross section of the pad PA perpendicular to the substrate SU is a trapezoid that shrinks in the direction away from the substrate SU.

As shown in FIG. 6 to FIG. 16, the shape of the orthogonal projection of the pad PA on the substrate SU can be a shape surrounded by smooth curves such as a circle and an ellipse, or a polygon such as a rectangle and a pentagon, or a “cross” shape, a “X” shape and other structures with multiple branches extending radially outward, and the shape is not specifically limited here.

For the embodiment in which the light-emitting devices LD are divided into a plurality of pixels in the above text, for the light-emitting device LD with a flip-chip structure, each light-emitting device LD is welded to two pads PA. Based on this, as shown in FIG. 2, FIG. 3 and FIG. 14, the pads PA can be divided into a plurality of welding units PAU, and the welding units PAU are provided in an array. One welding unit PAU may include two adjacent pads PA, and the two pads PA of one welding unit PAU may be welded to the first electrode and the second electrode of one light-emitting device LD. In addition, the distance between two adjacent welding units PAU is the distance between a pad PA in one welding unit PAU and a pad PA in another welding unit PAU, where the pad PA in one welding unit PAU and the pad PA in another welding unit PAU are arranged adjacently.

The two pads “adjacent” herein means that there is no other pad between the two pads.

The inventors found that in the eutectic bonding between the above-mentioned conductive solder SO and the pad PA, since the light-emitting device needs to withstand a certain pressure, the melted conductive solder SO overflows to the surroundings due to being squeezed, and the overflow range is the range beyond the boundary of the pad PA; it may cause a short circuit between adjacent pads PA. In order to reduce the risk of short circuit, the distance between adjacent pads PA can be limited, and the distance should be greater than the overflow range of the conductive solder SO, so as to prevent the pad PA from short circuiting in the event of overflow. After testing and analysis, the overflow range of the conductive solder SO is usually greater than 10 μm, so the distance between adjacent pads PA should be greater than 20 μm. However, for high-resolution display panels, the spacing between the light-emitting devices is difficult to meet the requirement of greater than 20 μm, and the risk of the above-mentioned short-circuit problem is relatively high.

Based on the above analysis, the inventor proposes that the overflow range can be limited by designing the structure of the binding layer BL, rather than simply increasing the spacing between the light-emitting devices. The following is a detailed description:

### First Idea

The local area of the pad PA can be defined as a welding part 10, and a flow limiting groove 20 recessed toward the substrate SU is opened outside the welding part 10, and the boundary of the pad PA is located outside the flow limiting groove 20. When eutectic bonding is performed, the conductive solder SO can be stacked on the welding part 10. When the conductive solder SO overflows due to melting, at least a part of it can enter the flow limiting groove 20 and be blocked, so that it is difficult to contact the adjacent pad PA, improving the short-circuit problem caused by overflow.

As shown in FIG. 2 to FIG. 7, in a first type of embodiment of the first idea, the flow limiting groove 20 may be a closed annular structure having two concentrically arranged closed side walls, namely, an inner side wall and an outer side wall surrounding the inner side wall. The part of the pad PA surrounded by the flow limiting groove 20 is the welding part 10. The shape of the contour of the orthogonal projection of the flow limiting groove 20 on the substrate SU may be circular, elliptical, or a polygon such as a rectangle, and its shape is not specifically limited here.

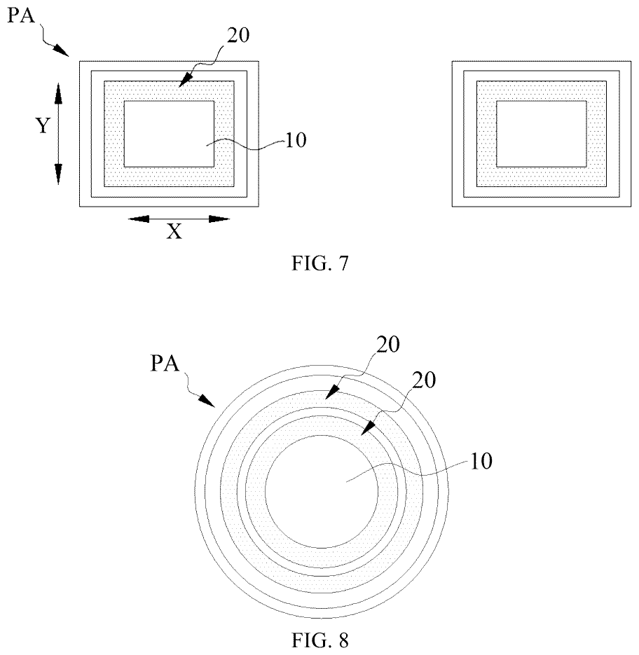

The extending track of the flow limiting groove 20 may be the same as the contour of the orthogonal projection of the pad PA on the substrate SU. That is, the shape of the contour of the orthogonal projection of the flow limiting groove 20 on the substrate SU may be the same as the shape of the contour of the orthogonal projection of the pad PA on the substrate SU, and the centers of the two projections may coincide. For example, as shown in FIG. 7, the shape of the contour of the orthogonal projection of the pad PA on the substrate SU is a rectangle, and the shape of the contour of the orthogonal projection of the flow limiting groove 20 on the substrate SU is also a rectangle. As shown in FIG. 6, the shape of the contour of the orthogonal projection of the pad PA on the substrate SU is circular, and the shape of the contour of the orthogonal projection of the flow limiting groove 20 on the substrate SU is also circular.

The depth of the flow limiting groove 20 does not exceed the thickness of the pad PA. Take the pad PA including the seed layer PA1 and the conductive layer PA2 mentioned above as an example:

In some embodiments of the first type of embodiments, as shown in FIG. 4, the flow limiting groove 20 is recessed from the surface of the conductive layer PA2 away from the substrate SU to the substrate SU, and its depth is less than the thickness of the conductive layer PA2. That is, the bottom surface of the flow limiting groove 20 covers the seed layer PA1. The flow limiting groove 20 can be formed by etching the conductive layer PA2, and the depth of the flow limiting groove 20 is less than the thickness of the conductive layer PA2, which is conducive to reducing the difficulty of etching. For these embodiments, during manufacturing, a seed layer PA1 can be prepared on the driving backplane BP first, and patterned by a photolithography process (coating photoresist, exposure, development, etching, etc.); then a conductive layer PA2 is formed by a process such as electroplating; on the basis of the patterned seed layer PA1, a patterned conductive layer PA2 can be naturally formed by an electroplating process, and then a flow limiting groove 20 is formed on the pad PA by a photolithography process, and the depth of the flow limiting groove 20 can be controlled by controlling the etching amount.

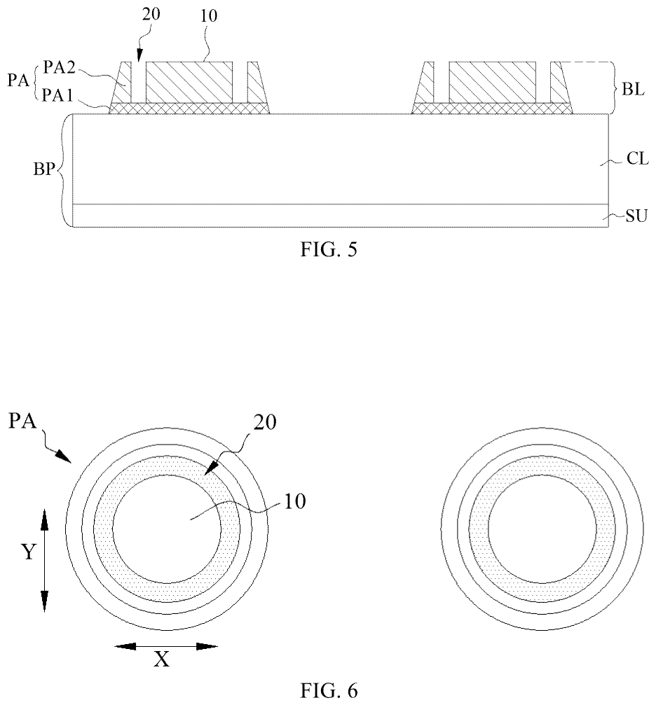

In some embodiments of the first type of embodiments, as shown in FIG. 5, the depth of the flow limiting groove 20 can be the same as the thickness of the conductive layer PA2, so that the flow limiting groove 20 exposes the seed layer PA1, and the bottom surface of the flow limiting groove 20 is the surface of the seed layer PA1 away from the substrate SU. At this time, the flow limiting groove 20 can completely divide the conductive layer PA2, so as to accommodate more conductive solder SO and improve the effect of blocking overflow. For these embodiments, during manufacturing, a seed layer may be first formed on the driving backplane BP, but it may not be patterned, and the seed layer PA1 is a whole layer structure; then, a photoresist that defines the pattern of the conductive layer PA2 is formed on the seed layer PA1; and then, the material of the conductive layer PA2 is electroplated at a position without the photoresist by electroplating or other processes, for example, thick copper is electroplated to obtain a patterned conductive layer PA2 with a flow limiting groove 20. The depth of the flow limiting groove 20 is consistent with that of the conductive layer PA2. Then, the photoresist that defines the pattern of the conductive layer PA2 is removed, and a photolithography process is performed again, the purpose of which is to remove the patterned seed layer PA1 between conductive layers PA2 to obtain multiple pads PA.

In some embodiments of the first type of embodiments, the depth of the flow limiting groove 20 may also be greater than the thickness of the conductive layer PA2. That is, the flow limiting groove 20 may extend into the seed layer PA1, or even penetrate the seed layer PA1.

In some embodiments of the first type of embodiments, as shown in FIG. 8, a plurality of flow limiting grooves 20 may be provided on the same pad PA, and each flow limiting groove 20 may be concentrically distributed around the welding part 10. That is, the flow limiting grooves 20 have different sizes and surround the welding part 10 layer by layer from the inside to the outside. Thus, the effect of blocking the overflow of the conductive solder SO can be improved by using a plurality of flow limiting grooves 20. Of course, since the area of the pad PA is limited, in order to ensure that the welding part 10 has sufficient area to contact the conductive solder SO, the number of flow limiting grooves 20 may be set to no more than three.

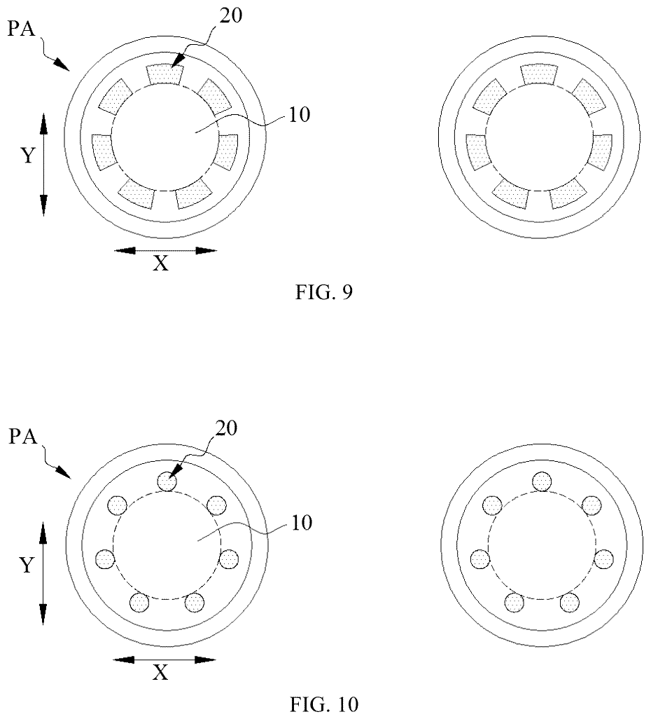

In a second type of embodiments of the first concept, as shown in FIG. 9 to FIG. 13, there are multiple flow limiting grooves 20, and they are spaced around the welding part 10. That is, the function of blocking the overflow of the conductive solder SO can also be achieved through multiple array-distributed flow limiting grooves 20 that are not connected to each other. Here are some examples:

The flow limiting grooves 20 can be spaced along an annular track around the welding part 10. Since there is no flow limiting groove 20 in an area between two adjacent flow limiting grooves 20 on the pad PA, the area is continuous. The shape of the aforementioned annular track can be the same as the shape of the contour of the orthogonal projection of the pad PA on the substrate SU, and the shape can be rectangular, circular, etc., which is not specifically limited here.

As shown in FIG. 9 to FIG. 12, in some embodiments of the second type of embodiments, the flow limiting grooves 20 can be spaced along the same annular track, and the inner side wall of the flow limiting groove 20 and its extended surface can be the boundary of the welding part 10. That is, although the flow limiting grooves 20 are spaced, the boundary of the welding part 10 can still be divided. The aforementioned annular track can be the same shape as the boundary of the pad PA.

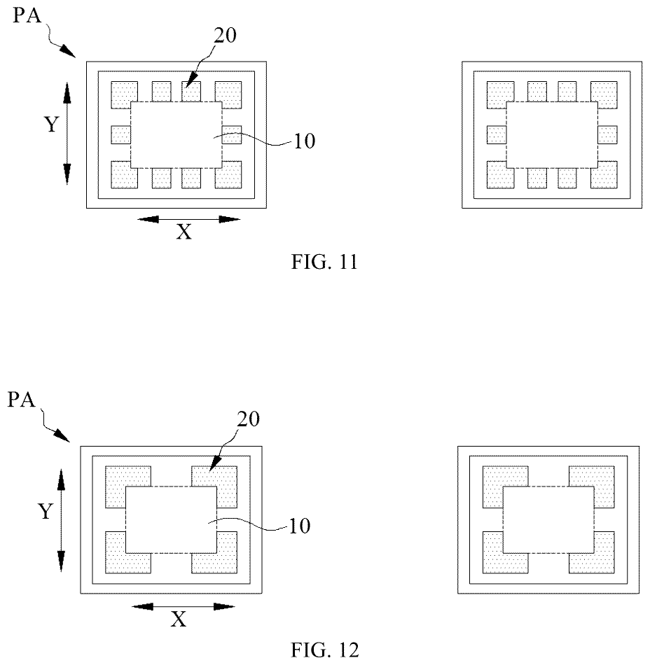

For example, as shown in FIG. 9, the flow limiting groove 20 may be an arc-shaped structure, and a plurality of flow limiting grooves 20 may form a circular welding part 10. As shown in FIG. 11 and FIG. 12, the flow limiting groove 20 may be a rectangular or L-shaped structure, and a plurality of flow limiting grooves 20 may form a rectangular welding part 10. Of course, the rectangular welding part 10 may also be formed by four L-shaped flow limiting grooves 20.

In some embodiments of the second type of embodiments, the flow limiting groove 20 can also be a blind-hole-structured groove with a circular, elliptical or polygonal shape, and multiple flow limiting grooves 20 can be distributed along the same annular track. At this time, the range surrounded by the boundaries simultaneously connected to the flow limiting grooves 20 can be regarded as the welding part 10. For example, as shown in FIG. 10, each flow limiting groove 20 can be circular and distributed along a circular track, and the range of the circumscribed circle that is externally tangent to the flow limiting grooves 20 is the welding part 10. If each flow limiting groove 20 is a polygon with the vertex toward the center of the pad PA, the pad PA within the range of the line connecting each vertex can be regarded as the welding part 10, and the line can be a straight line or a curve.

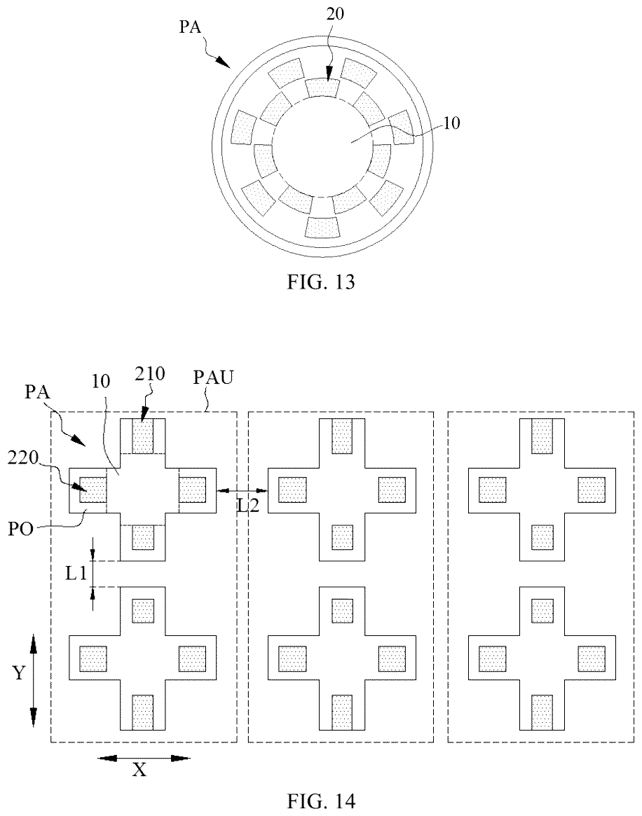

In some embodiments of the second type of embodiments, as shown in FIG. 13, the flow limiting grooves 20 can be divided into multiple groups, and the same group of flow limiting grooves 20 can be distributed along the same annular track surrounding the welding part 10, and different groups of flow limiting grooves 20 can be distributed along different annular tracks concentrically surrounding the welding part 10, so that multiple circles (one circle is a group) of flow limiting grooves 20 can be set to block the overflow of the conductive solder SO.

Further, as shown in FIG. 13, in order to improve the blocking effect, two adjacent circles of flow limiting grooves 20 can be staggered in the radial direction. That is, one of the flow limiting grooves 20 of one circle is located between two flow limiting grooves 20 in an adjacent circle of flow limiting grooves 20. In the case where both circles of flow limiting grooves 20 are arranged at intervals, the conductive solder SO can be blocked from overflowing by staggering the two circles of flow limiting grooves 20, thereby reducing the risk of the conductive solder SO overflowing from between the two flow limiting grooves 20.

### Second Idea

In some embodiments of the second idea, as shown in FIG. 14 to FIG. 16, the spacing between adjacent pads PA is uneven. That is, for a pad PA, it is arranged adjacent to multiple pads PA, and at least two pads PA adjacent to the pad PA have different spacing distances from the pad PA, so that the spacing distances between the pads PA exhibit a size hierarchy. At this time, part of the flow limiting grooves 20 can be set as grooves with open structures, which can be defined as open flow limiting grooves 210. The side wall of the open flow limiting groove 210 has a notch, which faces the aforementioned pad PA with a larger spacing distance therebetween, and the conductive solder SO can be led out of the open flow limiting groove 210, making full use of the larger spacing distance to accommodate the conductive solder SO.

For example, any pad PA is taken as a target pad, and pads PA adjacent to the target pad PA includes a first pad and a second pad. The distance between the first pad and the target pad is a first distance, and the distance between the second pad and the target pad is a second distance. The first distance is greater than the second distance.

The target pad is provided with flow limiting grooves 20, and at least one flow limiting groove 20 is the above-mentioned open flow limiting groove 210, and the open flow limiting groove 210 is open toward the first pad, so that the conductive solder SO entering the open flow limiting groove 210 can overflow to the first pad. In the case where the amount of conductive solder SO is relatively large and there is a risk of overflowing the flow limiting groove 20, a drainage groove can guide the overflow direction to overflow to the first pad far away from the target pad PA, thereby minimizing the risk of short circuit.

For a pad PA, it can be provided with only one open flow limiting groove 210, or it can be provided with both an open flow limiting groove 210 and a closed flow limiting groove 220. The closed flow limiting groove 220 is a circumferentially closed groove, i.e., a closed flow limiting groove 220. The closed flow limiting groove 220 can block the conductive solder SO, while the open flow limiting groove 210 can guide the conductive solder SO to overflow to the pad PA at a farther distance. While blocking, it can also achieve drainage, thereby minimizing the risk of short circuits caused by overflow of the conductive solder SO on adjacent pads PA.

The following is an example description of the setting of the flow limiting groove 20 in combination with pads PA of different shapes and distribution modes:

In some embodiments, as shown in FIG. 14, the pad PA includes a plurality of radially extending branches PO. At least one of the branches PO is provided with a closed flow limiting groove 220, and at least one of the branches PO is provided with an open flow limiting groove 210, and the closed flow limiting groove 220 and the open flow limiting groove 210 are located in different branches PO. The open flow limiting groove 210 is open toward a pad PA with the largest distance from the pad PA where the open flow limiting groove 210 is located along the extending direction of the branch PO where the open flow limiting groove 210 is located.

As shown in FIG. 14, taking the “cross”-shaped pad PA as an example, it has four branches PO, and an open flow limiting groove 210 can be set in one branch PO, and the other three branches PO are provided with closed flow limiting grooves 220. The closed flow limiting grooves 220 can be distributed along the same rectangular track around the center of the pad PA, and the pad PA within the range surrounded by the track is the welding part 10.

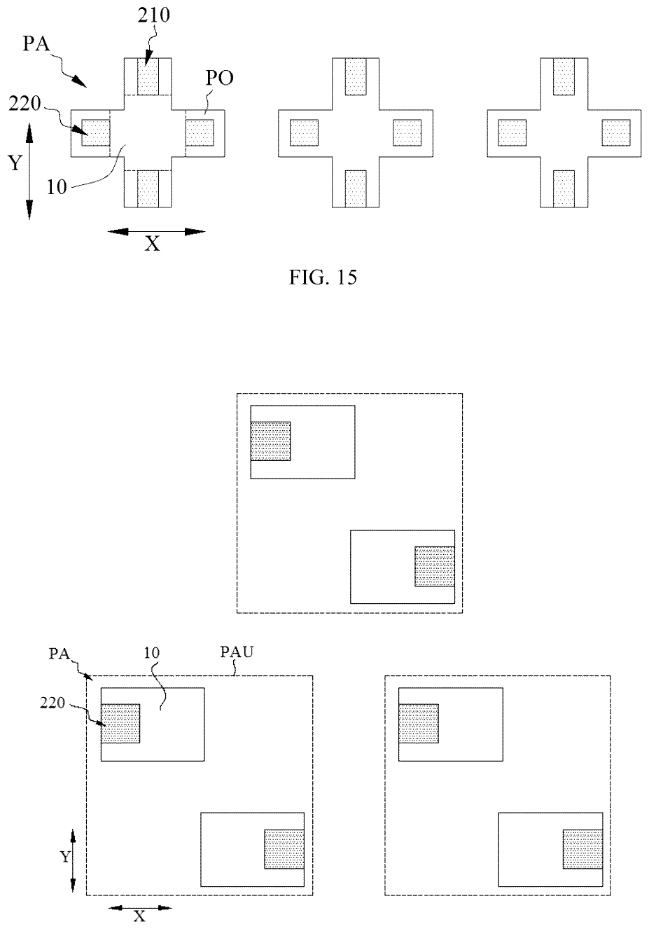

As shown in FIG. 15, if the light-emitting device LD is a vertical structure, one light-emitting device LD is welded to one pad PA. The light-emitting devices LD and their welding pads PA can be distributed in a rectangular array along the row direction X and the column direction Y. The distance between two adjacent rows of pads PA is greater than the distance between two adjacent columns of pads PA. That is, the distance between two adjacent pads PA in the row direction X is greater than the distance between two adjacent pads PA in the column direction Y. At the same time, the pad PA has two branches PO extending along the column direction Y and two branches PO extending along the row direction X, and an open flow limiting groove 210 is respectively provided on the two branches PO extending in the column direction Y, and the notches of the two open flow limiting grooves 210 are in opposite directions. Other branches PO can be provided with closed flow limiting grooves 220.

As shown in FIG. 14, if the light-emitting device LD is a flip-chip structure, one light-emitting device LD is welded with two pads PA. That is, one light-emitting device LD is welded with one welding unit PAU. The light-emitting devices LD and their pads PA can be distributed in a rectangular array along the row direction X and the column direction Y. The spacing LI between the two pads PA of the welding unit PAU is less than the distance L2 between the welding units PAU. At the same time, the pad PA has two branches PO extending along the column direction Y and two branches PO extending along the row direction X. Each of the two pads PA of the same welding unit PAU has a branch PO with an open flow limiting groove 210, and the notches of the two open flow limiting grooves 210 are in opposite directions and are open toward other welding units PAU. Other branches PO may be provided with closed flow limiting grooves 220.

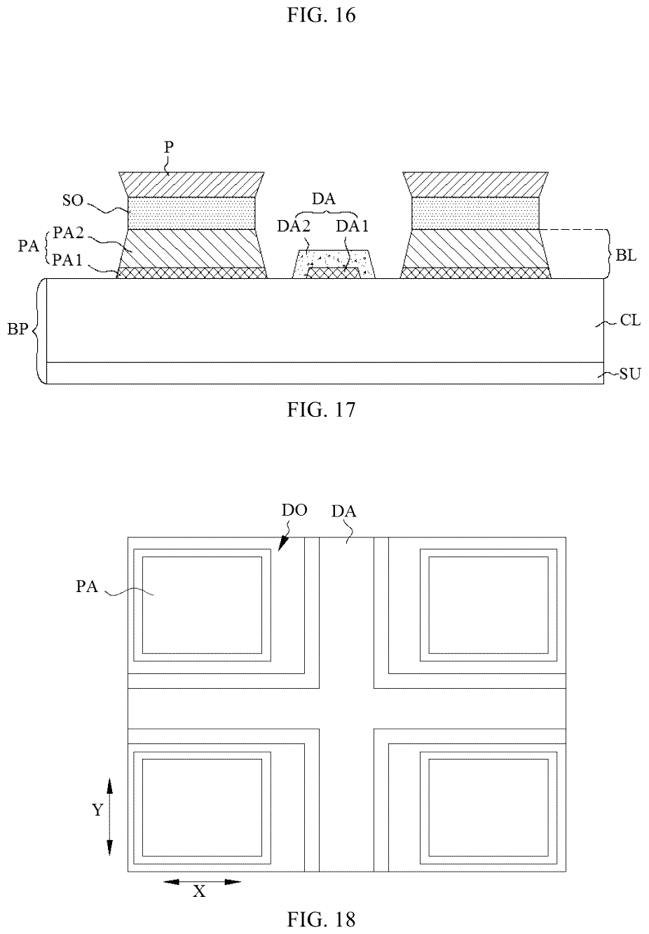

If the pad PA is not the above-mentioned “cross” shape, but a polygon such as a circle, an ellipse or a rectangle, and the light-emitting device LD is the above-mentioned flip-chip structure, each pad PA may also be provided with only one flow limiting groove 20, which is an open flow limiting groove 210. The notches of the two flow limiting grooves 20 of the two pads PA of the same welding unit PAU are in opposite directions. For example, as shown in FIG. 16, the orthogonal projection of the pad PA on the substrate SU is a rectangle, and the three light-emitting devices LD of the same pixel are distributed in a triangle. Correspondingly, the welding units PAU connected to the three light-emitting devices LD are also distributed in a triangle. Each of the two pads PA of the same welding unit PAU is provided with a flow limiting groove 20, and the flow limiting groove 20 is an open flow limiting groove 210. The notches of the two open flow limiting grooves 210 of the two pads PA of the same welding unit PAU are open in the back.

It should be noted that the above-mentioned open flow limiting groove 210 and the closed flow limiting groove 220 are both arranged in the flow limiting groove 20. For the concentrically arranged multi-circle flow limiting groove 20, the open flow limiting groove 210 is located in the outermost circle.

In addition, for the above-mentioned first and second ideas, the area of the orthogonal projection of the flow limiting groove 20 on the substrate SU can be made smaller than the area of the orthogonal projection of the welding part 10 on the substrate SU, ensuring that the pad PA has enough surface to contact the conductive solder SO and ensure the conductive performance.

### Third Idea

As shown in FIG. 17, blocking structures DA spaced apart from the pads PA can be provided between the pads PA, and the blocking structures DA are insulated from the pads PA, so that the conductive solder SO can be blocked by the blocking structures DA, reducing the risk of short circuit between adjacent pads PA.

At least part of the blocking structures DA can be connected as an integral structure, so that they can be formed at the same time, which is conducive to simplifying the process.

In some embodiments of the third idea, as shown in FIG. 18, all the blocking structures DA can be connected as an integral structure. At this time, the blocking structures DA can be regarded as a whole layer structure with multiple openings DO, and a pad PA can be set in each opening DO, so that each pad PA is surrounded by the blocking structure DA. The shape of the opening DO can be the same as the shape of the contour of the pad PA, and the distances between the side wall of the opening DO and any point on the edge of the pad PA can be equal to ensure uniform blocking effect everywhere. Of course, the distances between different areas of the side wall of the opening DO and the pad PA can also be different.

In some embodiments of the third idea, the blocking structures DA can be discontinuous and arranged at intervals. For example, a circle of blocking structures DA can be set around each pad PA, and a circle of blocking structures DA is distributed at intervals along a circular track, as long as it has a certain effect of blocking the conductive solder SO. A single blocking structure DA can extend along a straight line or a curve, depending on the shape of the pad PA. The track of the distribution of the blocking structures DA can be the same as the shape of the pad PA or different. The contour of a single blocking structure DA may also be circular, elliptical, square, etc., surrounding the pad PA in a lattice manner.

In some embodiments of the third idea, the thickness of the blocking structure DA can be made smaller than the thickness of the pad PA, so that the blocking structure DA is located on the surface of the pad PA away from the substrate SU but on the side of the surface close to the substrate SU, thereby preventing the blocking structure DA from contacting the light-emitting device LD and avoiding interference with the welding of the light-emitting device LD and the pad PA. Of course, the thickness of the blocking structure DA can also be equal to the thickness of the pad PA, but should not be greater than the thickness of the pad PA.

The blocking structure DA can be a single-layer or multi-layer structure, and the part thereof that contacts the conductive solder SO is made of insulating material. In some embodiments of the third idea, as shown in FIG. 17, the blocking structure DA may include a blocking conductive layer DA1 and a blocking insulating layer DA2. The blocking conductive layer DA1 and the pad PA may be provided on the same surface of the driving backplane, and the blocking insulating layer DA2 may cover the blocking conductive layer DA1. The blocking insulating layer DA2 may extend from the side wall of the blocking conductive layer DA1 to the driving backplane BP and contact the surface of the driving backplane BP, thereby covering the blocking conductive layer DA1 and preventing the blocking conductive layer DA1 from contacting the external. The blocking conductive layer DA1 may be made of metal or alloy material, which is formed by processes such as sputtering and electroplating, and the blocking insulating layer DA2 may be made of inorganic insulating materials such as silicon nitride and silicon oxide. The thickness of the blocking structure DA may be increased by the blocking conductive layer DA1 and the blocking insulating layer DA2, and the effect of blocking the conductive solder SO may be improved, and the blocking insulating layer DA2 may prevent short circuits.

In some embodiments, as shown in FIG. 17, the pad PA includes a seed layer PA1 and a conductive layer PA2. The blocking conductive layer DA1 can be provided in the same layer as the seed layer PA1, so that the blocking conductive layer DA1 can be formed simultaneously with the seed layer PA1 through the same process, which is conducive to simplifying the process. At the same time, after the seed layer PA1 and the blocking conductive layer DA1 are formed, the blocking insulating layer DA2 can be formed first, and then the conductive layer PA2 of the pad PA is formed by electroplating and other processes.

In some embodiments of the present disclosure, the embodiments of the first idea and the second idea mentioned above can be combined with the embodiment of the third idea in any feasible way. That is, as shown in FIG. 19, while there is a flow limiting groove 20 in the pad PA, a blocking structure DA can still be provided between the pads PA to prevent short circuits between the pads PA due to overflow of the conductive solder SO to the greatest extent. As for the specific scheme of the flow limiting groove 20 and the blocking structure DA, please refer to the content about the flow limiting groove 20 and the blocking structure DA above, which will not be described in detail here.

When the light emitting device LD is welded to the pad PA through the conductive solder SO, the atomic mass ratio of the welding product can be limited by controlling the thickness of the conductive solder SO and the pad PA, combined with the initial area of the welding part 10 and the conductive solder SO, that is, the atomic mass ratio of the eutectic bonding product can be limited, so as to ensure good conductivity and fixing performance.

In some embodiments of the present disclosure, taking the pad PA having a continuous annular flow limiting groove 20 surrounding the welding part 10 as an example, the material of the conductive layer PA2 of the pad PA is copper, and the material of the conductive solder SO is tin. The area of the orthogonal projection of a boundary on the substrate SU can be defined as a first area, the boundary is a boundary of the flow limiting groove 20 on the surface of the pad PA away from the substrate SU, and the initial area when the conductive solder SO contacts the pad PA is defined as a second area. In order to limit the overflow range, the first area: the second area>1:3, and at the same time, the ratio of the thickness of the conductive layer PA2 to the thickness of the conductive solder SO can be 3:1, so that the eutectic bonding product can be mainly Cu3Sn, that is, the atomic weight ratio of copper to tin is 3:1.

In some embodiments of the present disclosure, the material of the pad PA is gold, and the material of the solder is tin. At this time, the atomic weight ratio of gold to tin in the welding product of the pad PA and the conductive solder SO can also be controlled by controlling the area and thickness in the above-mentioned embodiments. For example, the atomic weight ratio of gold to tin can be not less than 2 and not more than 3.5; the first area: the second area is not more than 1:2 and not less than 1:7.

The present disclosure also provides a display device, which may include a display panel of any embodiment mentioned above. The display panel is a display panel of any embodiment mentioned above, and its specific structure and beneficial effects can refer to the embodiments of the display panel above, which will not be repeated here. The display device of the present disclosure can be a mobile phone, a tablet computer, a TV, or an electronic device with a display function such as a smart watch, a smart bracelet, and a car display, which will not be listed one by one here.

After considering the specification and practicing the present disclosure herein, those skilled in the art will easily think of other embodiments of the present disclosure. This application is intended to cover any variation, use or adaptation of the present disclosure, which follows the general principles of the present disclosure and includes common knowledge or customary technical means in the technical field not disclosed in the present disclosure. The description and examples are to be regarded as exemplary only, and the true scope and spirit of the present disclosure are indicated by the appended claims.

1. A driving backplane, comprising:
a substrate;
a circuit layer, provided on a side of the substrate;
a binding layer, provided on a side of the circuit layer away from the substrate, wherein the binding layer comprises a plurality of pads distributed in an array;
wherein each of the pads comprises a welding part and a flow limiting groove located outside the welding part, and a boundary of the pad is located outside the flow limiting groove;
and/or, blocking structures spaced apart from the pads are provided between the pads, and the blocking structures are insulated from the pads.

2. The driving backplane according to claim 1, wherein the flow limiting groove is a closed annular structure.

3. The driving backplane according to claim 1, wherein there are a plurality of flow limiting grooves for each pad and the plurality of flow limiting grooves are spaced apart around the welding part.

4. The driving backplane according to claim 1, wherein a thickness of the blocking structure is less than a thickness of the pad.

5. The driving backplane according to claim 1, wherein at least part of the blocking structures is connected as an integral structure.

6. The driving backplane according to claim 5, wherein each of the blocking structures comprises a blocking conductive layer and a blocking insulating layer covering the blocking conductive layer.

7. The driving backplane according to claim 2, wherein an extending track of the flow limiting groove is same as a contour of an orthogonal projection of the welding part on the substrate.

8. The driving backplane according to claim 3, wherein the flow limiting grooves on a same pad are distributed along a track with a same shape as a contour of an orthogonal projection of the welding part on the substrate.

9. The driving backplane according to claim 1, wherein each of the pads comprises a seed layer and a conductive layer stacked in sequence in a direction away from the substrate; and
a depth of the flow limiting groove is less than or equal to a thickness of the conductive layer.

10. The driving backplane according to claim 6, wherein each of the pads comprises a seed layer and a conductive layer stacked in sequence in a direction away from the substrate; and
the blocking conductive layer is provided in the same layer as the seed layer.

11. The driving backplane according to claim 1, wherein any of the pads is a target pad; pads adjacent to the target pad comprises a first pad and a second pad; a distance between the first pad and the target pad is a first distance, and a distance between the second pad and the target pad is a second distance; the first distance is greater than the second distance;
the flow limiting groove comprises an open flow limiting groove, and the open flow limiting groove is a groove with a partial area of a side wall open; and
the target pad is provided with the open flow limiting groove, and the open flow limiting groove of the target pad is open toward the first pad.

12. The driving backplane according to claim 11, wherein the flow limiting groove further comprises a closed flow limiting groove, and the closed flow limiting groove is a circumferentially closed groove;
each of the pads comprises a plurality of branches extending radially; at least one of the branches is provided with the closed flow limiting groove, and at least one of the branches is provided with the open flow limiting groove; and the closed flow limiting groove and the open flow limiting groove are located in different branches.

13. The driving backplane according to claim 11, wherein the pads are divided into a plurality of welding units, and the plurality of the welding units are arranged in an array;
one welding unit comprises two adjacent pads; a distance between two pads of a same welding unit is greater than a distance between two adjacent welding units; and
the two pads of the same welding unit are respectively provided with an open flow limiting groove, and the open flow limiting grooves of the two pads are open toward opposite directions.

14. The driving backplane according to claim 11, wherein an area of an orthographic projection of the flow limiting groove on the substrate is smaller than an area of an orthographic projection of the welding part on the substrate.

15. The driving backplane according to claim 3, wherein the flow limiting grooves are divided into a plurality of groups, the flow limiting grooves of a same group are arranged along a same annular track around the welding part, and the flow limiting grooves of different groups are arranged along different annular tracks concentrically around the welding part.

16. A display panel, comprising:
the driving backplane according to claim 1; and
a plurality of light-emitting devices, wherein any one of the light-emitting devices is welded with the welding part of at least one pad through a conductive solder.

17. The display panel according to claim 16, wherein a material of the pad comprises copper, a material of the solder comprises tin; in a welding product formed by welding the pad and the conductive solder, an atomic weight ratio of copper to tin is 3.

18. The display panel according to claim 16, wherein a material of the pad comprises gold, a material of the solder comprises tin; in a welding product formed by welding the pad and the conductive solder, an atomic weight ratio of gold to tin is 2 to 3.5.

19. A display device, comprising the display panel according to claim 16.
